(19) United States
(12) Patent Application Publication
(10) Pub. No.: US 2024/0219477 A1
(43) Pub. Date: Jul. 4, 2024

(54) METHOD AND DEVICE FOR MEASURING AND ESTIMATING THE STATE OF CHARGE AND THE STATE OF AGING OF A BATTERY

(71) Applicant: ECOTHEA S.R.L., Torino (IT)

(72) Inventors: Aurelio SOMÀ, Torino (IT); Francesco MOCERA, Torino (IT)

(73) Assignee: ECOTHEA S.R.L., Torino (IT)

(21) Appl. No.: 18/685,527

(22) PCT Filed: Jun. 23, 2022
(86) PCT No.: PCT/IB2022/055841

§ 371 Date: Feb. 22, 2024

(30) Foreign Application Priority Data
Jun. 24, 2021 (IT) 102021000016583

(51) Int. Cl. G01R 31/392; G01B 5/30; G01R 31/387; H01M 10/42; H01M 10/48; H01M 10/625; H01M 50/136

(52) U.S. Cl. CPC G01R 31/392; G01B 5/30; G01R 31/387; H01M 10/425; H01M 10/482; H01M 10/486; H01M 10/625; H01M 50/136; H01M 2010/4278; H01M 2220/20

(57) ABSTRACT

An electrical device comprising at least one battery cell having a casing which houses anode and cathode elements, an electronic management module (BMS) comprising an electronic control unit for managing at least one battery cell, at least one deformation sensor applied to the cell casing for detecting the geometric deformation of at least one surface area of the cell casing and electrically connected to the electronic control unit, a signal conditioning algorithm performed by the electronic management module (BMS) which is programmed to calculate according to a mathematical model the current state of health (SOH) and/or the current state of charge (SOC) of the at least one battery cell (C) operating as a function of a signal generated by the deformation sensor and representative of a current deformation of the cell.

### CROSS REFERENCE TO RELATED APPLICATIONS

This application is a national stage entry of International Application No. PCT/IB2022/055841, filed on Jun. 23, 2022, which is based upon and claims foreign priority to Italian Patent Application No. 102021000016583, filed on Jun. 24, 2021, the entire contents of which are incorporated herein by reference.

### TECHNICAL FIELD

The present invention refers to a system for accurately determining the state of charge and aging and/or health of at least one battery pack, which battery pack can comprise one or a plurality of battery cells which, depending on the use, can be grouped into battery modules. The invention is generally applicable to any device operating through electric charge accumulators, for civil and/or industrial use.

### BACKGROUND

The use of batteries to power devices operating on electric current has been known for some time and the spread of such devices is constantly increasing, both for consolidated applications and for emerging applications and nowadays more and more common in the civil and industrial fields. Examples of such applications are personal electronic devices (laptops, palmtops, wearables), energy storage systems from discontinuous sources such as photovoltaics, urban mobility with assisted traction (cycles), electric vehicles in the automotive and industrial fields and so on.

Such devices are generally equipped with rechargeable electric accumulators of which a more or less marked deterioration with use is known, which involves a worsening of the accumulation capacity and delivery of the electric charge, as well as the difficulty in accurately estimating the quantity of electric charge still available in the discharge phase (when the accumulator generates electric current and transfers energy to the user load) and in the charging phase (when the accumulator absorbs electric energy from an external electric source to make it subsequently available).

If historically the charging and discharging phases generally took place interspersed with relatively long periods of time, the increase in systems and methods for recovering secondary energy such as kinetic energy during braking of a vehicle subject the accumulators to more frequent charging/discharging micro-cycles thus increasing the stress and performance required to be suitable for the required use.

It is therefore increasingly felt the need to establish the state of charge (SoC) and the state of health (SoH) of the batteries with extreme precision in order to monitor their performance, safety (cases of explosions or fires of cells damaged or subjected to incorrect operating conditions are not rare) and accurately predict the residual autonomy of the devices whose operation depends on these batteries, processing and presenting precise indications in real time, for example, of the kilometers that can still be travelled or the operating hours of lighting or heating devices

Once the state of health of the batteries is known, it is possible to activate preventive maintenance actions in order to assist the user in planning the necessary actions, such as the replacement of the accumulator, or part of it, by replacing a module of the battery pack or the complete battery according to the configuration with which the device is equipped.

The estimate of the state of charge and the state of health of the batteries, i.e. of the individual cells that define a battery pack, cannot be limited to the measurement of the no-load voltage at the terminals of the batteries themselves as this measurement is unsatisfactory in terms of the result, although easier to apply. Even if combined with other types of tests such as resistance/impedance or temperature measurement, the estimate of the battery conditions is not sufficiently accurate or reliable. Consequently, the prior art contemplates systems operating on the basis of the deformation of the casing, or swelling, of the batteries being monitored in order to determine their operating conditions as well as the state of health (SoH) of the cell intended as a measure, usually expressed as a percentage from 0% to 100%, indicative of the condition of the same over time and of its ability to accumulate and supply electric current at a certain length of service compared to the nominal performance, i.e. as new, equal to 100% of SoH.

The state of health, sometimes referred to as the state of aging or aging, cannot be measured in terms of time of use of the battery itself, nor be limited to the number of charge and discharge cycles of a rechargeable cell, as several other factors affect the performance degradation such as the intensity of the discharge or charge currents, the depth of discharge (DoD), the operating temperatures and in general the environmental operating conditions.

In general, monitoring and management of a battery pack are combined with a special control system commonly known as the Battery Management System or BMS, which can be implemented as a standalone unit, or in the form of one or more electronic boards integrated into the battery device, or also in the form of a software algorithm that processes direct or indirect information from the battery.

The BMS is able to acquire status signals from battery elements as well as from other elements of the user device (e.g. the battery charger module) with which it interacts and coordinates in order to determine the operating parameters and control the charging and discharging phase of accumulators. Among the main roles, the BMS is generally involved in the measurement and estimation of the state of charge (SoC) and, more rarely, the state of aging or health (SoH) of the accumulator.

Regarding the battery, many types have been developed over the years. The batteries most often used are the enveloped ones (pouch) because they allow a higher degree of adaptability to the specific implementation or very often also cylindrical or prismatic modules. Generally, these are lithium-ion modules.

One or more electrochemical battery cells, herein also referred to as “battery cells” or simply “cells”, can be comprised to form a battery; depending on the specific field of application, more cells are grouped together to form a module and more modules form a battery, which can more precisely be referred to as a “battery pack”.

For example, in the automotive field, a hybrid or electric vehicle comprises one or more battery packs. A battery pack comprises one or more modules and each module comprises one or more cells.

The composition in modules is advantageous for uses in which the replacement of battery pack components is intended without the intervention of the parent company or specialized workshops, think for example of a damaged or underperforming battery in a storage system in difficult areas to reach or in an industrial or agricultural machinery. Furthermore, in these cases, the replacement of a battery pack or module is not always facilitated by the working conditions of the user device, therefore the replaceable elements must be easy to replace and, preferably, do not requiring special tools or precision operations or that can only be performed by skilled labor, as this would complicate replacement operations up to putting at risk the integrity and operation of the entire device. Therefore, in addition to having a precise estimate of the current charge level and state of health, is a felt need that the replacement of one or more removable parts is carried out simply, quickly and without specialized tools.

Document US 2015/0160302 deals with a method and a system for estimating the current state of health of a battery in terms of aging starting from an initial state using a strain gauge applied to the battery which, at a predetermined level of charge, compares a first deformation initially detected with a second deformation detected at the current state of aging and aims to determine an estimate of the degradation of the battery as a function of the difference between the two detected deformation levels.

From the studies and tests carried out by the Applicant on this prediction methodology, it appears that, although it is an improvement with respect to the systems previously described, such approach still suffers from a certain degree of uncertainty, in particular for the following reasons:
the strain gauge is applied to the battery surface rather than to the single cell, a method rather sensitive to measurement and calibration errors and highly dependent on the stiffness of the battery pack support structure which introduces a noisy component to the measurement as a result of the vibrations transmitted by the environment outside the battery pack. This is particularly relevant in the case of industrial and/or automotive applications due to the obvious conditions resulting from the movement of the vehicle;
it is assumed that with the same aging and state of charge there is a unique deformation value that can be detected on the cell casing. As better detailed below, the Applicant's studies have shown that this hypothesis is not reflected in reality.

Document WO2017/087807A1 discloses an electrical device comprising a battery and a BMS which includes a controller in electrical connection with a pressure sensor for monitoring the state of health of the battery. The controller determines the state of health as a function of the force measured by the sensor in combination with the analysis of the incremental capacity based on the force values measured by the sensor to estimate the degradation of battery performance. Even this document, although operating in a different way, suffers from the limitations already reported for the document US 2015/0160302. In addition, the deformation of the entire battery pack occurs through a force sensor which acts in the longitudinal direction opposing and measuring the force resulting from the expansion of the set of cells arranged side by side to define the pack, a construction that further penalizes the effectiveness of the measurement and external measurement noise insulation.

US-A1-2017307693 describes a magnetic sensor fixed on a battery casing and able to detect a swelling deformation on a secondary battery thanks to the fact that, on the latter, a layer of polymeric material with a charge of magnetic powders is applied, e.g. rare earths, iron, nickel etc. Therefore, an element of perturbation or generation of a magnetic field i.e. the layer is applied to the swelling wall and the sensor is applied to a more rigid structure adjacent to that wall. This makes the magnetic sensor subject to relative displacements with respect to the layer with magnetic powders e.g. as a result of vibrations and this negatively impacts the accuracy of the measurement in conditions of use e.g. if the vehicle is traveling along a bumpy path.

US-A1-20140107949 explicitly describes a measuring tool for the force generated when swelling a battery. The document also mentions the possibility of using deformation sensors but does not indicate the position of application, which could for example be on the tool and not on the cell.

In the present application, reference can be made to the concept of depth of discharge (DOD) as an alternative to the concept of state of charge (State Of Charge—SOC), meaning that the former is the complementary state of the latter, e.g. a 30% DoD equals a 70% SoC.

### SUMMARY

The scope of the present invention is to provide a device capable of accurately determining the current state of the charge level and the state of health of a battery pack, the device operating in accordance with a method which is also the aim of the invention.

Another purpose of the present invention is to provide a device which, in achieving the aforementioned purpose, is easily integrable with a battery pack comprising several modules and can be assembled/disassembled without particular precision tools and through operations that can be easily performed even by non-specialized operators.

The invention achieves these and other purposes by means of an electrical device comprising:
at least one battery cell comprising a deformable casing which houses anode and cathode elements electrically connected to an anode electrode and to a cathode electrode and subject to swelling during charging and discharging cycles;
an electronic management module (BMS) comprising an electronic control unit for managing said at least one battery cell;
at least one deformation sensor applied to the, i.e. carried by said cell casing for detecting the geometric deformation of at least one surface area of said cell casing and electrically connected to said electronic control unit;
a signal conditioning algorithm performed by the electronic management module (BMS) which is programmed to calculate, according to a mathematical model, the current state of health (SOH) and/or the current state of charge (SOC) of the at least one cell battery (C) operating in function:
for the current state of charge (SOC), of a signal generated by the said deformation sensor and representative of a current deformation of the cell to which said deformation sensor is applied;
and also, for the state of health (SOH), of the current state of charge or discharge of the cell to which the said deformation sensor is applied.

The battery cell, preferably of the Lithium-Iron-Phosphate (LFP) type, can be used individually or grouped in modules and/or in a set of modules to form a battery pack. The choice of the type is made, by the skilled man in the art, according to the device to be powered e.g. a single cell for a palmtop device or a battery pack for a vehicle for civil, agricultural or industrial use. The deformation can be considered both in terms of displacement of the wall subject to swelling, and of variation of the thickness of the cell, as well as of an adjusted parameter i.e. the relationship between the measured displacement and a reference dimension e.g. the cell thickness at rest.

Different variants of the invention are applicable which, without departing from the inventive scope, provide for different deformation sensors, possibly in combination or alternatively. Differently from the prior art, it is provided that at least one sensor is preferably positioned on the surface of the single cell or of the single module, since it has been found that the arrangement on the battery surface is sensitive to measurement and calibration errors and is highly dependent from the stiffness of the battery pack support structure which introduces a noisy component to the measurement as a result of the vibrations transmitted from the external environment to the battery pack.

According to a variant embodiment, the deformation sensor is an extensometer (strain gauge) capable of detecting the deformation (swelling) of at least part of the surface of the casing which contains anode and cathode elements in one, two or three directions. Such strain gauge is of a type known to those skilled in the art which, by way of non-limiting example, could be of the Wheatstone resistive bridge type. Preferably, such extensometer, which measures the deformation in a punctual area of the wall subject to swelling, is positioned in a position which maximizes the detectable deformation, e.g. at L/4 considering that at L/2 the maximum widening of the cell occurs, wherein L is one side of the cell e.g. the long side.

In alternative variants or variants combined with the previous one, deformation sensors can be used which provide in different modalities, such as for example optical sensors.

The signal generated by the sensor, or by several sensors in case of a battery pack, is transferred to a battery management battery module (BMS) which processes it, preferably together with the information signals from other units of the system that houses the battery, such as part of the control and supervision that the BMS exercises over the battery itself. The BMS therefore comprises at least one electronic control unit, including a processing unit, at least one non-volatile memory and at least one communication unit, which houses the operating steps which determine, among other things, the estimate of the state of charge (SoC) and the state of health (SoH) of the battery.

In the present invention, differently from what is known, the estimate of the state of health is obtained according to a mathematical model which acts by combining the signal generated from the deformation sensor which represents the current formation of the cell with the state of charging or discharging of the current cell itself.

The Applicant has reached such formulation having observed the presence of a hysteresis cycle characteristic of the cell due to the characteristics of the different materials of the anode and cathode and of the different deformation behaviors induced by the insertion of the atoms of active material during the charging and discharging cycles. Such hysteresis cycle was identified by plotting the charge and discharge curves of a cell in a Cartesian plane defining a two-dimensional space representing the experimental relationship between the state of charge SoC with percentage unit of measurement and the deformation of the battery cell casing (swelling).

Such SoC-Swelling characteristic curve has a different trend, only minimally superimposed, if the cell is in the discharging phase rather than if the cell is in the charging phase. A hysteresis cycle of the SoC-Swelling characteristic was therefore highlighted. It has also recently been demonstrated that this hysteresis characteristic is intrinsic to the electro-chemical-mechanical behavior of the cell as a function of the type of materials of the cell. For example, as the charging-discharging current varies and with the same SOH, the position of the local maxima and minima of the hysteresis area can be considered with a good approximation constant.

These characteristics have therefore inspired the definition of the algorithm for determining the state of health, which operates by linking the deformation detected by the swelling sensor with the punctual operating condition of the battery, differentiating the case of charging from the case of discharging.

The present invention also presents a method for measuring the swelling of a battery cell for estimating a state of health of the battery cell on the basis of a SOC-swelling deformation curve having a local maximum and minimum. Such method is simple and precise and can also be implemented outside a laboratory, e.g. in a vehicle workshop, in order to check the SOH of a battery cell with precise tools and/or in a controlled environment and then evaluate a total or partial overhaul of the battery pack of a hybrid or full-electric vehicle.

### BRIEF DESCRIPTION OF THE DRAWINGS

FIGS. 1 to 3 attached to the present application show part of the experimental results found by the Applicant supporting the inventive concepts of the invention;

FIGS. 4 to 6 show a possible embodiment wherein a battery pack (FIGS. 5 and 6) comprises a plurality of prismatic-shaped modules on which a deformation sensor is applied (FIG. 3).

### DETAILED DESCRIPTION OF THE EMBODIMENTS

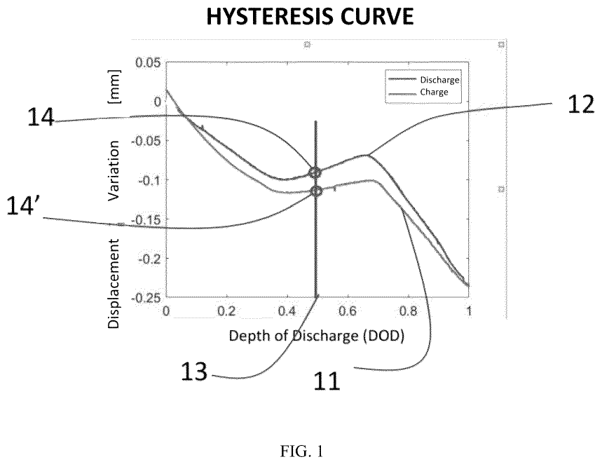

As also evident in FIG. 1, which shows a hysteretic trend obtained by representing a charging cycle 11 and a discharging cycle 12 of the same cell in a Cartesian plane showing the SoC and swelling values, to a single SoC 13 value correspond two different swelling values 14, 14′ depending on the current state of the battery, which can therefore be a state of charge 11 or a state of discharge 12. Advantageously, introducing such reference in the calculation algorithm allows to considerably improve the estimate of the state of health of the battery and achieve at least one of the scopes of the invention. To achieve this benefit, the invention provides that the BMS is aware of, and therefore stores, the current state of charge or discharge of the cell to which said deformation sensor is applied.

The deformation of the cell with respect to the state of charge in the SoC-Swelling plane does not present a monotonous trend but is reproducible with a curve with three characteristic zones 21, 22, 23. It has been observed that this behavior is an electro-mechanical characteristic due to the electrical coupling due to the migration of charges between anode and cathode in combination with the mechanical behavior characteristics of the materials. In the lithium-iron phosphate cells, which are currently among the most used in hybrid electric vehicles, a pronounced hysteresis characteristic with three zones is observed and in the central zone 22 an inversion of the expansion into contraction behavior 24 or vice versa 25 depending on the level of charge in correspondence with swelling values (thickness change) which differ according to whether the cell is charged or discharged. This effect has recently been studied in the literature with laboratory tests without developing the applicable possibility of the correspondent hysteresis curve.

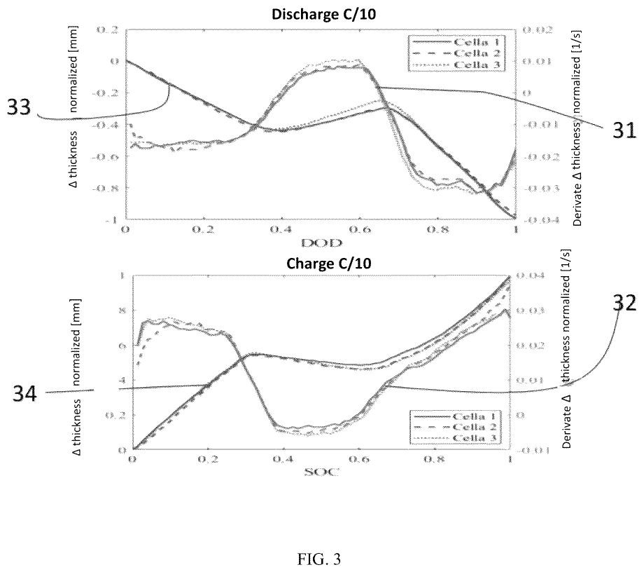

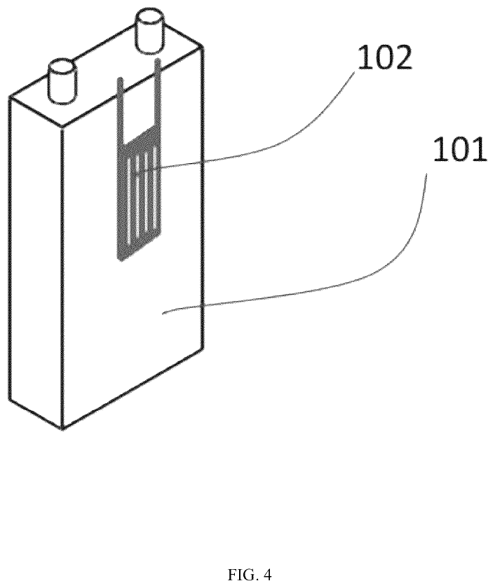

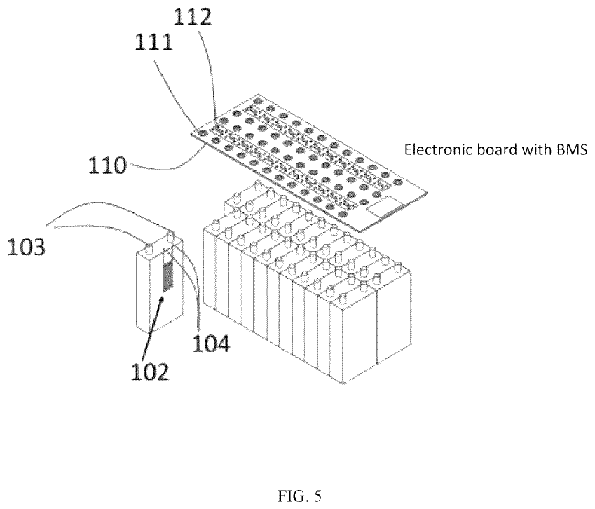

In one embodiment, the electronic management module is programmed for the determination of the SoH State of Health of the battery cell on the basis of a charging condition of the battery cell at constant current (for example C/2 or C/10 as shown in the figure, where C is the nominal value of the charging or discharging current) and on the basis of the evaluation of the variation of the position on the SOC axis of the transition points of the derivative of the SOC-swelling curve, or in the curves shown in FIG. 3 and indicated with 31 and 32, respectively for the charging phase and for the discharging phase; the example shows the characteristic curves of three similar battery cells in a charging and discharging condition at C/10, i.e. one tenth of the nominal current of the battery cell. Curves 31 and 32 show the trend of the variation of the deformation, and as can be seen such trend has at least two substantially flat areas in correspondence with the central areas of the three regions 21, 22, 23. The behavior of such indicator can be used, alternatively or in combination, with a variant of the invention according to which the electronic management module is programmed for the determination of the State of Health SoH of the battery cell on the basis of a discharging condition of the battery cell at constant current and on the basis of the evaluation of the change in the position of the transition points of the derivative of the SOC-swelling curve over time. In particular, a transition point of the derivate comprises a sign reversal point, which refers to a maximum or minimum of the SOC-swelling curve.

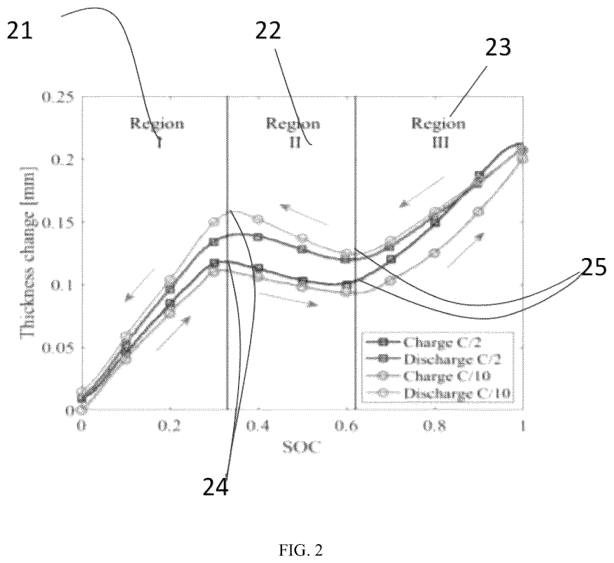

As described, the deformation of the cell with respect to the state of charge in the SoC-Swelling plane does not present a monotonous trend but is reproducible with a curve with three characteristic zones. These three zones, identified in the three regions I, II, III of FIG. 2, are defined by maximum and minimum points and are delimited by a change in slope of the curves drawn there. It should be noted that different values of charge intensity (Charge C/2 and Charge C/10) and discharge (Discharge C/2 and Discharge C/10) at constant current give rise to different graph trends, while maintaining a hysteretic type profile. The border areas between the regions therefore represent a local minimum or maximum and therefore transition points of the derivative (FIG. 3). In particular, such minimum or maximum points can be considered with good approximation in a constant SOC position as the charging/discharging current varies.

Having experimentally observed how cell aging involves the shifting of the SoC values corresponding to said transition points of the curve derivative, the invention determines the SoH by tracking of such shift as the charging and/or discharging cycles proceed and analysing the variation of the transition points between Region I/II and Region II/III and also evaluating the numerical distance (delta SoC) between the corresponding SoC values.

This delta SOC allows you to operate as follows:
If the measured delta SOC remains constant upon repetition of the charging/discharging cycles but the state of charge measured by an external measuring element, for example a Coulomb counter, is not estimated exactly due to any accumulation of errors due to the estimation algorithm of the state of charge, it allows to make corrections to such algorithm.
If the delta SOC varies with the repetition of the charging/discharging cycles, it is confirmed that a physical property inside the battery cell has changed and therefore we are in conditions of aging or degradation of the state of health of the cell.

According to an executive variant, the control unit contains a numerical description, preferably in matrix format, of the possible mappings between the swelling values, the SoC values, the operating mode of the battery cell (charging or discharging) and the intensity of the current electricity that transits from or to the cell itself.

This numerical description, stored in one of the memories of the control unit, is used to estimate the state of charge as a function of the remaining parameters made available by the swelling sensor and by a sensor of intensity and direction of electric current that affects the cell. Advantageously, the differentiation of the calculation also considering the operating mode of the cell (charged or discharged) allows to significantly improve the accuracy of the estimate of the residual charge.

The above mapping can be preloaded on the basis of experimental measurements on the cell itself or on a cell similar to the nominal values of a new cell and is updated according to the processing of the maximum and/or minimum points that occur between the different regions as stated above.

According to an executive variant, the electrical device object of the invention comprises two or more battery cells 101 wherein said battery cells are mechanically and electrically interconnected in a releasable manner to an electronic power board 100 equipped with tracks and metallizations for the electrical connection of power and comprising connection seats 111, 112 for the electrical connection and for the rigid and releasable mechanical coupling to said strain gauge terminals 104 and/or to said cell terminals 103 of said electrical device.

In accordance with this variant, a battery pack is provided formed by a plurality of cells or modules 101, preferably having a prismatic shape, an electronic board hosting a BMS and comprising a plurality of through openings at the terminals of the plurality of operationally arranged modules, and a plurality of screws or nuts for locking said single electronic board with/on the terminals of said plurality of modules, and wherein said electronic board comprises tracks and metallizations so that the locking of the electronic board on the terminals of the plurality of modules also determines their respective electrical power connection in series and/or in parallel according to a pre-ordered connection scheme.

Advantageously, no electric wires are used, much less connections to be welded.

In a further variant of the previous embodiment, the two or more battery modules 101 are arranged side by side and spaced apart by a known distance (D) in such a way that at least a subset of said anode terminals are arranged along a rectilinear and parallel segment to a second segment on which at least a subset of said cathode electrodes lies and wherein said electronic power board comprises seats for electrical connection and mechanical fixing to said electrodes by means of threaded members of electrically conductive material. Advantageously, the deformation sensor element is glued to the surface of the single cell which is free to deform in the longitudinal direction because the battery pack is mounted so as to leave space between one cell and another.

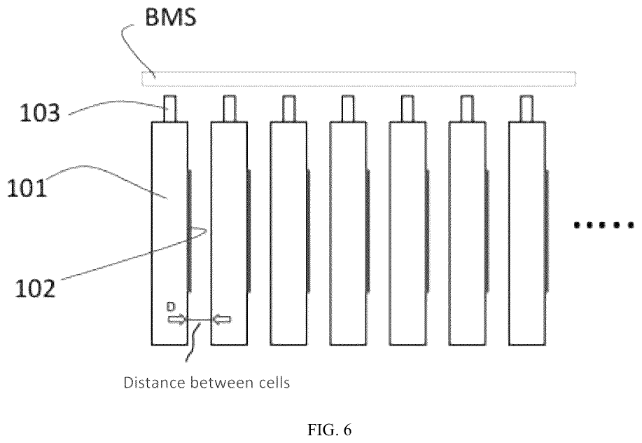

In an alternative or combined variant to the previous one, sensors for measuring the distance D between the cells (FIG. 6) are used, such as active and passive proximity sensors that can exploit phenomena of electromagnetic coupling, ultrasound or any other non-contact method for measuring that distance.

Implementation variants of the described non-limiting example are possible, without however departing from the scope of protection of the present invention, including all the equivalent embodiments for a person skilled in the art, to the content of the claims.

According to a further embodiment of the invention, a measurement method based on the SOC-swelling curve is provided and applicable when a battery pack is checked after disassembly from its use device e.g. disassembled from the car or scooter to evaluate with more precise measuring instruments than those applied to the deformable wall for swelling or in controlled conditions e.g. temperature suitable for obtaining more precise measurements than those performed while the battery pack is mounted on the corresponding device of use.

Such method includes the steps of:
detect a swelling deformation on a wall of a battery cell;
obtain a SOC-swelling deformation curve having at least a local maximum and a local minimum as transition points based on the detection phase e.g. as in FIGS. 1 and 2;
estimate a state of health of the battery cell 101 on the basis of the variation of the position:
either of the sign transition of a derivative of the SOC-swelling deformation curve;
or the transition points of the SOC-swelling deformation curve.

For example, the method can be performed by means of position measurements and, by difference, of displacement by means of a laser device in a controlled environment e.g. at a controlled temperature. By using the laser device, for example, it is possible to measure very precisely the point of the wall subject to swelling which has the greatest displacement during a charging/discharging cycle.

Furthermore, the method preferably comprises the step of measuring e.g. by means of a Coulomb counter or other charge capacity measuring devices. In this way, for example, it is possible to obtain a new chart as shown in FIGS. 1 and 2 updated to battery status e.g. after n-charging cycles. Such curve will show the local maximum and minimum displaced along the SOC axis with respect to the curve of the cell as new.

From the above description, the person skilled in the art is able to realize the object of the invention without introducing further construction details.

The vehicles for the use of the electrical device or battery pack are also floating and include wheel and/or propeller handling units, including wheel and/or propeller drones.

1. An electrical device comprising:
at least one battery cell comprising a deformable casing which houses anode and cathode elements electrically connected to an anode electrode and to a cathode electrode and subject to swelling during charging and discharging cycles of the cell;
an electronic management module comprising an electronic control unit for managing the at least one battery cell;
at least one deformation sensor applied to the cell casing for detecting the geometric deformation of at least one surface area of the cell casing and electrically connected to the electronic control unit;
a signal conditioning algorithm performed by the electronic management module which is programmed to calculate, according to a mathematical model, the current state of health and/or the current state of charge/state of discharge of the at least one battery cell operating in function:
for the current state of charge or discharge, of a signal generated by said deformation sensor and representative of a current deformation of the cell to which the deformation sensor is applied; and
for the state of health, of the current state of charge or discharge of the cell to which the deformation sensor is applied.

2. The electric device according to claim 1, wherein the electronic management module is programmed to receive a state of charge-swelling deformation curve having at least a local maximum and a local minimum as transition points; and
for the determination of the state of health of the battery cell on the basis of a state of charge of the same and on the basis of the evaluation of the variation of the position:
either of the sign transition of a derivative of the state of charge swelling deformation curve;
or the transition points of the state of charge-swelling deformation curve.

3. The electric device according to claim 1, wherein the electronic management module is programmed for the evaluation of the state of health on the basis of the discharging condition and the evaluation of the variation of the position of the sign transition of the derivative of a state of charge-swelling deformation.

4. The electric device according to claim 2, wherein the charging or discharging condition is at a known constant current value.

5. The electric device according to claim 1, wherein the electronic management module is programmed for the evaluation of the state of charge-swelling deformation curve at each battery charging cycle or evaluation of the state of charge-swelling deformation curve at each cycle discharging of the battery.

6. The electric device according to claim 1, wherein the at least one deformation sensor is an extensometer or strain gauge applied to the cell casing and detects the geometric deformation of at least one surface area of the casing.

7. The electric device according to claim 1, wherein the deformation sensor is provided with electric conductors for the exchange of electric signals towards at least one electric apparatus, which electric conductors comprise electromechanical terminals and connectors for the electrical connection and for the rigid and releasable mechanical coupling of the terminals in corresponding connection seats present in the at least one electrical apparatus.

8. The electric device according to claim 1, wherein the anode electrode and the cathode electrode are provided with terminals and electromechanical connectors for the electrical connection and for the rigid and releasable mechanical coupling in corresponding connection seats of the electrical apparatus.

9. The electric device according to claim 1, which further comprises at least one device for measuring the temperature in one or more areas of said battery cell and the consequent generation towards the electronic management module of measurement signals representative of the temperature detected.

10. The electric device according to claim 1, wherein the at least one deformation sensor is a sensor for evaluating the distance D between the cells by means of non-contact measurement.

11. The electric device according to claim 1, further comprising two or more battery cells wherein the battery cells are mechanically and electrically interconnected in a releasable manner by means of an electronic power board equipped with tracks and metallizations for the power electrical connection and comprising connection seats for the electrical connection and for the rigid and releasable mechanical coupling to the strain gauge terminals and/or to the cell terminals of the electrical device.

12. The electric device according to claim 11, wherein the two or more battery cells are arranged side by side and spaced apart by a known distance in such a way that at least a subset of the anode electrodes are arranged along a segment rectilinear and parallel to a second segment on which at least a subset of the cathode electrodes lies and wherein the electronic power board comprises seats for electrical connection and mechanical fixing to the electrodes by means of threaded members of electrically conductive material.

13. A vehicle comprising a handling system with an electric device according to claim 1.

14. A method of swelling measurement for estimating a state of health of a battery cell comprising: a deformable casing which houses anode and cathode elements electrically connected to an anode electrode and to a cathode electrode and subject to swelling during charging and discharging cycles of the cell; comprising the phases of:
detecting a preferably punctual swelling deformation of the battery cell wall;
obtain a state of charge-swelling deformation curve having at least a local maximum and a local minimum as transition points based on the detection phase; and
estimate a state of health of the battery cell on the basis of the variation of the position:
either of the sign transition of a derivative of the state of charge-swelling deformation curve;
or the transition points of the state of charge-swelling deformation curve.

15. The electric device according to claim 3, wherein the charging or discharging condition is at a known constant current value.

16. The electric device according to claim 2, wherein the at least one deformation sensor is an extensometer or strain gauge applied to the cell casing and detects the geometric deformation of at least one surface area of the casing.

17. The electric device according to claim 3, wherein the at least one deformation sensor is an extensometer or strain gauge applied to the cell casing and detects the geometric deformation of at least one surface area of the casing.

18. The electric device according to claim 4, wherein the at least one deformation sensor is an extensometer or strain gauge applied to the cell casing and detects the geometric deformation of at least one surface area of the casing.

19. The electric device according to claim 5, wherein the at least one deformation sensor is an extensometer or strain gauge applied to the cell casing and detects the geometric deformation of at least one surface area of the casing.

20. The electric device according to claim 2, wherein the deformation sensor is provided with electric conductors for the exchange of electric signals towards at least one electric apparatus, which electric conductors comprise electromechanical terminals and connectors for the electrical connection and for the rigid and releasable mechanical coupling of the terminals in corresponding connection seats present in the at least one electrical apparatus.
